(19) United States
(12) Patent Application Publication
(10) Pub. No.: US 2013/0295836 A1
(43) Pub. Date: Nov. 7, 2013

(54) Passive Airflow Vent for Electronic Device Cover

(71) Applicant: Robert James Shannon, III, Clermont, FL (US)

(72) Inventor: Robert James Shannon, III, Clermont, FL (US)

(21) Appl. No.: 13/461,992

(22) Filed: May 2, 2012

(51) Int. Cl. H05K 5/02

(52) U.S. Cl. CPC H05K 5/0213
USPC 454/284

(57) ABSTRACT

The invention is a vent within the cover of an electronic device through which air may flow freely by way of the structure of the design. Such flow of air is passive, in that it is not propelled by any mechanism, but flows by its own natural properties. The design characteristics of this vent may facilitate this flow of air, which may then provide the transfer of heated air through the cover and away from the electronic device.

### BACKGROUND

1. Field of the Invention

The present invention relates to the field of electronic devices. Specifically, the invention relates to a passive airflow vent within a cover applied to said device which allows airflow to pass through the cover. This unique design may allow transfer of air which may provide a release of temperature from electronic device.

2. Related Art

An electronic device, such as a computer tablet, may operate at an elevated temperature, and as such, may benefit from such a flow of air. Therefore, there is room for improvement within the art of electronic device cover design.

### SUMMARY OF INVENTION

A passive airflow vent design is disclosed. Said airflow vent may have a heatsink design which allows transfer of temperature. It may have unique design patterns and features which allow a flow of air from the electronic device to the outside. This flow of air may be beneficial to the operation of said device.

### DETAILED DESCRIPTION OF THE INVENTION

An exemplary design for a passive airflow vent is disclosed, as per the illustrations provided.

Electronic devices may have decorative covers applied. While the electronic device is turned to the ‘on’ position for an extended period of time, it may exhibit an elevation in temperature. Such an electronic device may benefit from a vent within said cover which may allow transfer of air.

The unique design of said airflow vent may include placement of pillars which may act as heatsinks. The unique patterns of said pillars may also facilitate the velocity of air to accelerate around said pillars; and said placement of pillars may allow for passage of air while the electronic device is held in various orientations. This passive airflow design may facilitate the transfer of air through said vent.

Aspects of the unique design of said airflow vent may include variations in pillar design and size which may contribute reinforcement of strength to said airflow vent, as demonstrated in the illustrations provided. Aspects of the unique design may also include variations in pillar placement and size to facilitate air flow.

Such a passive airflow vent design may be applied to electronic device covers or any other devices which may benefit from a transfer of temperature by an allowance of air flow via a passive design. The present invention is described primarily in the context of electronic devices. Possible examples of said electronic devices include, but are not limited to; computer tablets, communication devices, electronic readers, etc. Aspects of the present invention can be implemented in numerous and various electronic devices.

It is to be understood, however, that even though numerous characteristics and advantages of the exemplary invention have been set forth in the foregoing description and illustrations, the disclosure is illustrative only. It is further understood, that changes may be made in detail, especially in matters of shape, size, and arrangement of pillars and cutouts, within the principles of the invention, to the full extent indicated by the broad general meaning of the terms in which the claim is expressed.

### DESCRIPTIONS OF VIEWS OF THE DRAWINGS

FIG. 1 is an Electronic Device Cover which includes a Passive Airflow Vent. It is a perspective of all Sides in relation to each other; and a view of Front and Back perspectives.

FIG. 2 is a perspective of all Sides of Electronic Device Cover in relation to each other.

FIG. 3 is a perspective of the Electronic Device Cover from the back with Passive Airflow Vent displayed at the bottom left.

FIG. 4 is a perspective of the Front of the Electronic Device Cover with Passive Airflow Vent displayed at the bottom right.

FIG. 5 is a cut-away perspective of the Passive Airflow Vent

FIG. 6 is a front perspective of the Passive Airflow Vent

FIG. 7 is a three dimensional perspective of the back of the Electronic Device Cover; with the Passive Airflow Vent displayed at the bottom left.

FIG. 8 is a three dimensional close-up perspective of the back of the Passive Airflow Vent, highlighting the opening for airflow.

FIG. 9 is a three dimensional perspective of the Electronic Device Cover from the front with the Passive Airflow Vent displayed at the top left; demonstrates pillars and an airflow cut out.

FIG. 10 is a three dimensional close-up perspective of the Passive Airflow Vent displaying pillars and an opposing airflow cut out.

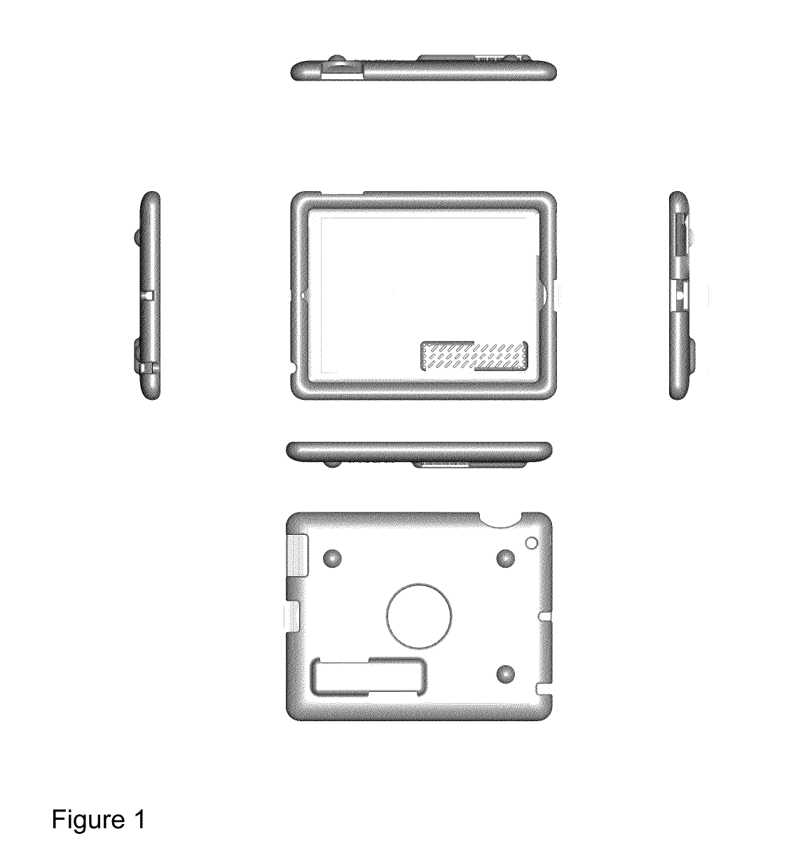

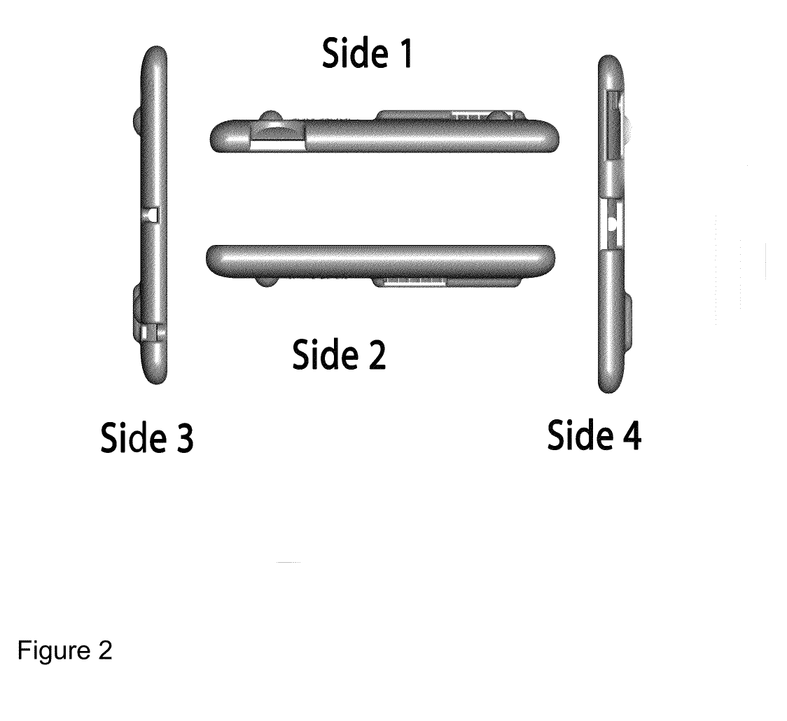

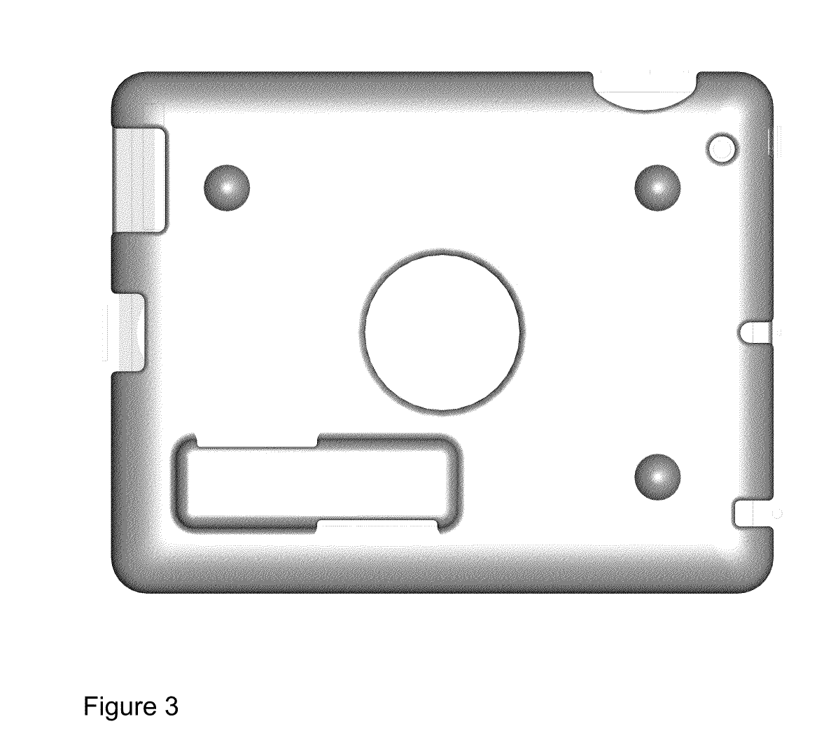

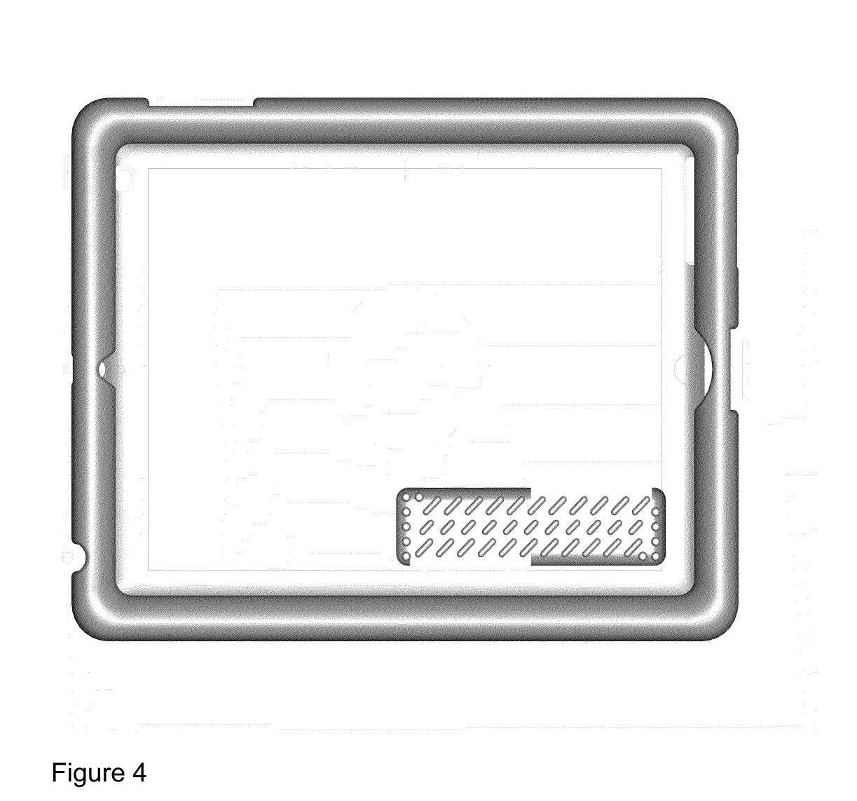

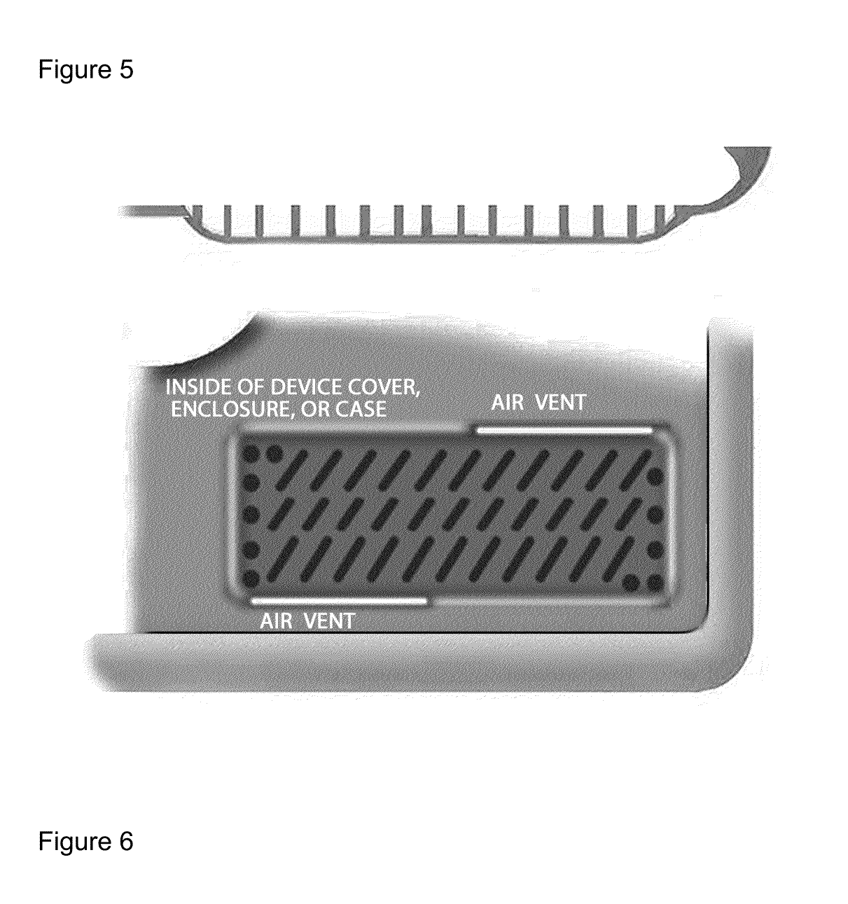

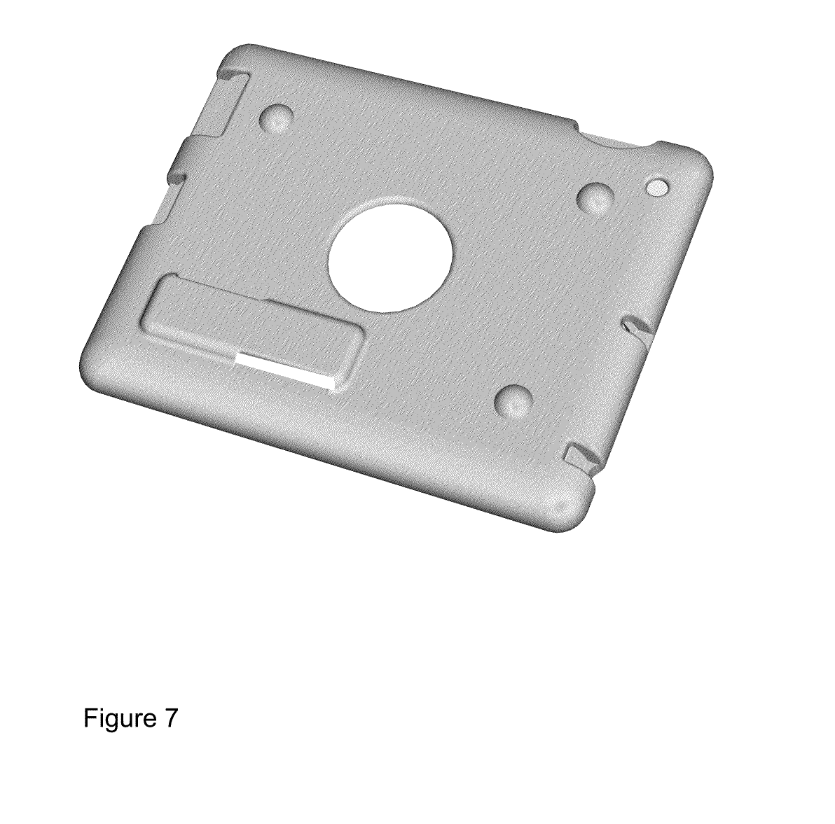

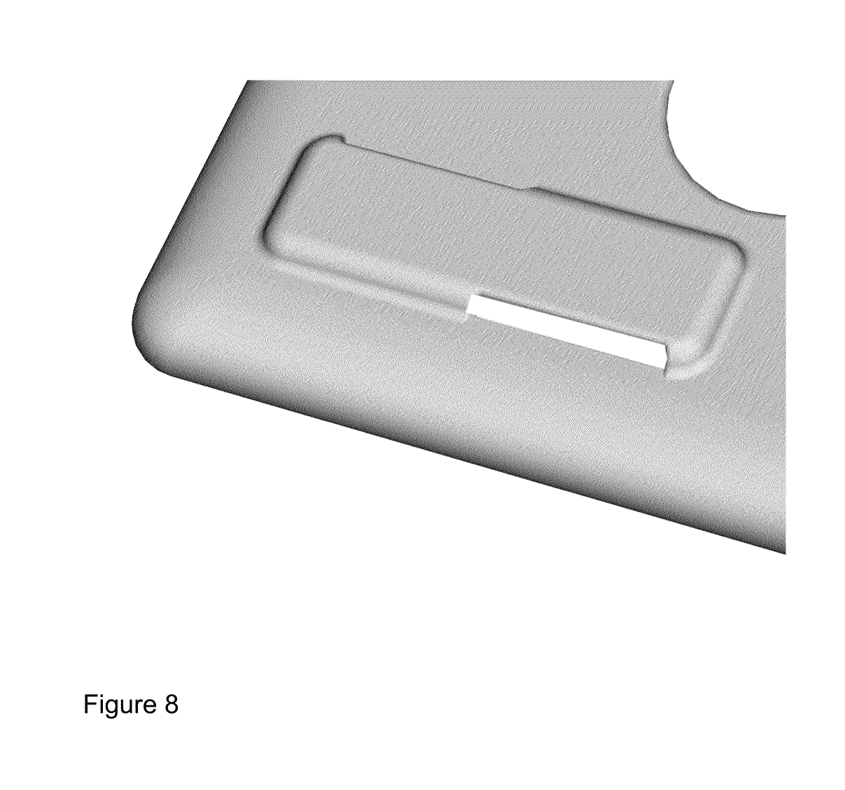

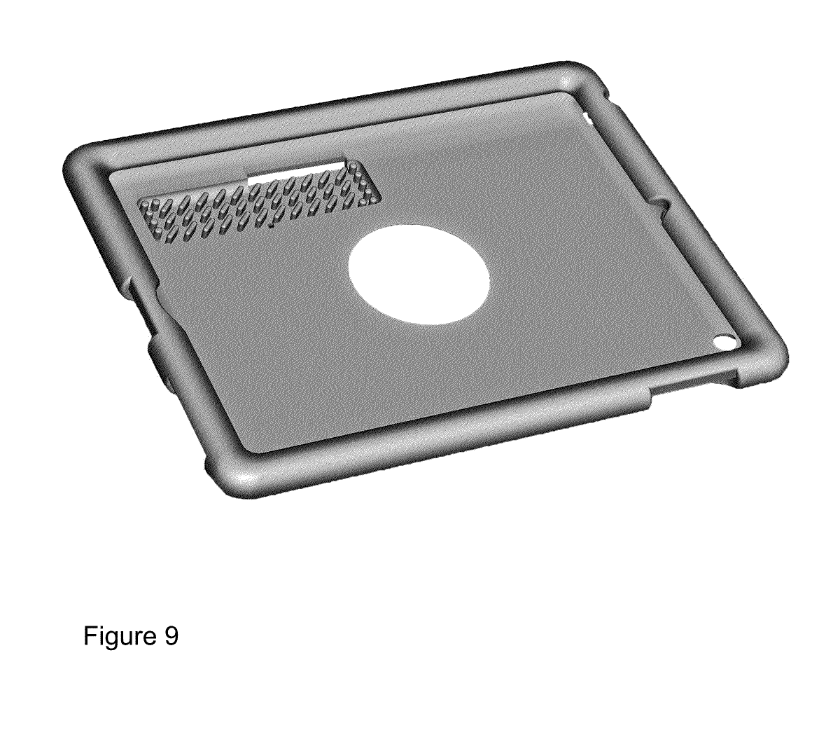

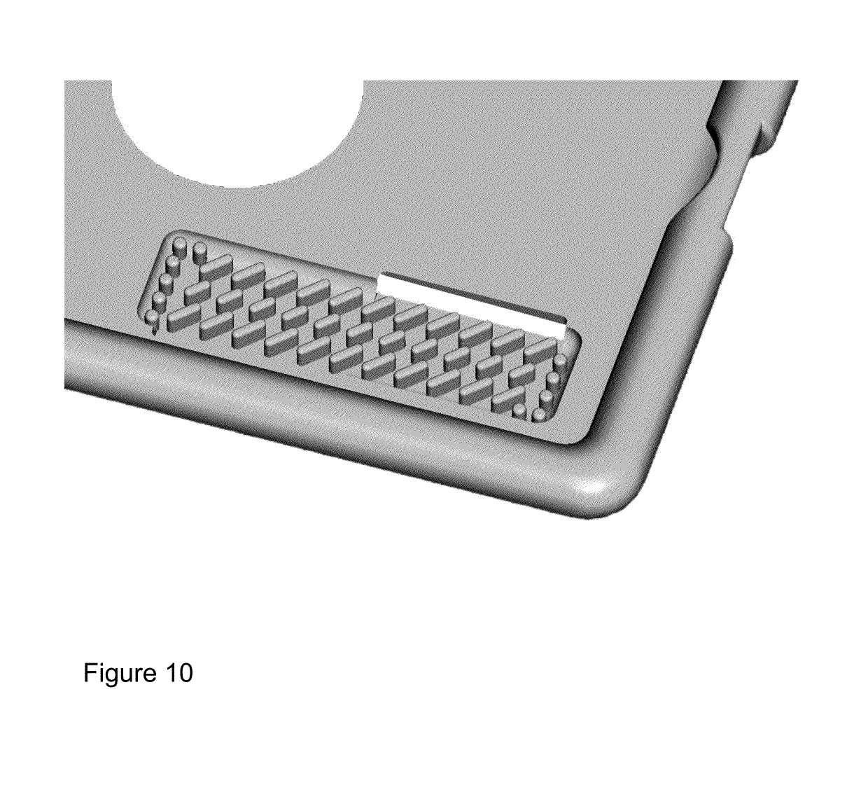

1. We claim the design for a passive airflow vent for an electronic device cover, as shown and described.
